(19) United States
(12) Patent Application Publication
(10) Pub. No.: US 2009/0172267 A1
(43) Pub. Date: Jul. 2, 2009

(54) REFRESH METHOD OF A FLASH MEMORY

(75) Inventors: Hiromichi ORIBE, Aichi-ken (JP); Teruki ORIHASHI, Aichi-ken (JP)

Correspondence Address: LOWE HAUPTMAN HAM & BERNER, LLP, 1700 DIAGONAL ROAD, SUITE 300, ALEXANDRIA, VA, 22314, US

(73) Assignee: HAGIWARA SYS-COM CO., LTD., Aichi-ken (JP)

(21) Appl. No.: 12/343,749

(22) Filed: Dec. 24, 2008

(30) Foreign Application Priority Data
Dec. 27, 2007 (JP) 2007-336047
Feb. 19, 2008 (JP) 2008-037139

(51) Int. Cl. G06F 12/02; G11C 11/34

(52) U.S. Cl. 711/103; 711/E12.008; 365/185.25

(57) ABSTRACT

A flash memory device includes a flash memory that stores many physical data blocks, a refresh management table that stores indications of the number of times each individual physical data block has been read, and a controller responsive to read and erase control signals from a source external to the flash memory device, and to the stored indications of the refresh management table for controlling reading, erasing and refreshing of the individual physical data blocks. In response to the number of times each individual physical data block has been read being equal to or exceeding a limit value, the controller refreshes the individual physical data block associated with the indication equaling or exceeding the limit value.

### RELATED APPLICATIONS

The present application is based on, and claims priority from, JP Application Number 2007-336047, filed Dec. 27, 2007, and JP Application Number 2008-037139, filed Feb. 19, 2008, the disclosures of which are hereby incorporated by reference herein in their entireties.

### FIELD OF THE INVENTION

The present invention relates to a method of and apparatus for refreshing a flash memory.

### BACKGROUND OF THE INVENTION

A flash memory is one type of electrically erasable and programmable read-only memory (EEPROM). A flash memory is a memory into which data are written (also called “programmed”) by charging capacitive cells located at intersections of word lines and bit lines. The written data are not lost as long as the electric charge is accumulated in the cell even if the power supplied to the cell is turned off. However, a so-called “read disturb error” can occur in a flash memory. A read disturb error is a phenomenon that, when data on a certain page of a certain physical block are frequently read out, data stored in a cell on other pages of the data block being read are changed.

Such a phenomenon occurs because, when data are read out from a selected cell, electric charge is injected into a floating gate of a non-selected cell, causing the non-selected cell to be virtually weakly programmed. Therefore, many more cells are affected as the number of times data are read from a physical data block increases. For this reason, a physical block of the flash memory must be refreshed (i.e. re-written) if the number of times data are read from the memory is relatively large. A limit on the number of times data can be read without executing a refresh is usually specified by the flash memory vendor, i.e. manufacturer. For example, among currently available products, a single-level cell (SLC) flash memory physical block must be refreshed when the number of data read cycles of a full particular physical block is in the range of 100,000 to 1,000,000 times, while a multi-level cell (MLC) flash memory physical block must be refreshed when the number of read data cycles is in the range of 10,000 to 100,000 times (generally, these limits tend to decrease as the number of data reading cycles of a particular physical block increases).

In the prior art refresh method, the number of read data cycles is counted for each physical block. In response to the number of times a host computer reading the data stored in such a physical block reaching the limit specified by the vendor, the data of such a physical block are refreshed by the host just after or just before the next time data are read from the block. For this reason, when plural physical blocks simultaneously reach the vendor specified limits the refreshes must be continuously executed. This makes maintaining a desired data transfer rate between the host and memory difficult. As a result, data transferred into the host might be temporarily interrupted to such an extent that a user of a machine including the host and memory is likely to be annoyed.

### SUMMARY OF THE INVENTION

Accordingly, an object of the present invention is to provide a flash memory refresh method and apparatus that efficiently and reliably prevents data from changing due to a read disturb error, and prevents transferring data to a host because of a temporary interruption to such an extent that a user of the data transfer is not annoyed, i.e. the user does not notice the interruption because it is so short or the transfer occurs while the user is not actively using the host. Other objects will be apparent from the specification, and the appended drawings and claims.

To provide a flash memory refresh method and apparatus that efficiently prevents data from changing due to a read disturb error, and prevents transferring data to a host because of a temporary interruption, 1) the flash memory device includes a refresh management table that stores, updates and manages, for each physical block in the flash memory, the number of times data are read and the number of times data are erased, and 2) a refresh flag is set for a particular physical block in response to the number of times data are read from the particular physical block reaching or exceeding a predetermined value, and 3) a refresh is executed according to the state of the flag.

In addition, in order to achieve the above-described objects, the present invention employs novel, characteristic configurations as defined in the claims which cover from a superordinate concept to a subordinate concept.

### BRIEF DESCRIPTION OF THE DRAWINGS

FIG. 1 is a block diagram of the basic configuration of a system for performing a preferred embodiment of the present invention.

FIG. 2 is an example of a refresh management table of the system of FIG. 1.

FIG. 3 is an example of the relation between a vendor-specified threshold value and a controller threshold, regarding the number of times data are read from a particular physical block of the flash memory of FIG. 1, vis-à-vis the number of times data are erased from the block.

FIG. 4 is an example of a method for performing a refresh operation in the system of FIG. 1.

FIG. 5 is an example of a refresh management table at the time a new flash memory system of the type illustrated in FIG. 1 is shipped to a customer by a vendor.

FIG. 6 is part 1 of a flow chart of a process performed by a controller of FIG. 1.

FIG. 7 is part 2 of the flow chart of the process performed by the controller.

FIG. 8 is part 3 of the flow chart of the process for performed by the controller.

### DETAILED DESCRIPTION OF THE DRAWINGS

Preferred embodiments of the present invention will now be described with reference to the accompanying drawings. However, the invention is not limited thereto and various changes and modifications can be made thereto without departing from the spirit and scope of the claims.

Basic System Configuration

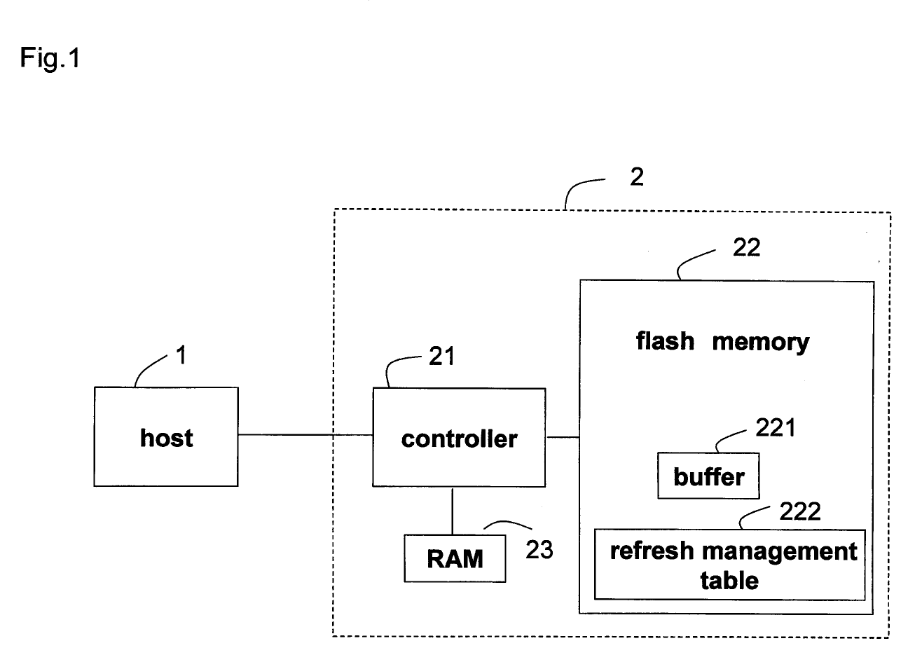

FIG. 1 comprises a system basically including: a flash memory device 2 having a NAND-type flash memory 22 (simply referred to as a “flash memory” in this specification except for cases where it must be referred to as “NAND-type flash memory”) and a controller 21 for writing and/or reading data to and/or from the flash memory 22. As is well known, the flash memory 22 includes multiple physical blocks, each having a number, i.e. address; flash memory 22 is considered to have 10,000 memory blocks, separately numbered 0-9999. These physical blocks store the user data. Flash memory 22 also includes blank blocks and spare blocks. The blank blocks are managed by controller 21 including and using a blank block table (not shown) and the spare blocks are managed by controller 21 including and using a spare block table (not shown). These tables exist in the management area of the flash memory 22. Blank blocks are used when the data stored in the any of physical blocks (0˜9999) are re-written. Spare blocks are used when the physical blocks have become bad blocks. Host 1 selectively issues, for a particular physical block of memory 22, a data write command and/or a data read command; the commands are issued to the device 2. To this end, each command issued by host 1 for memory 22 includes indications of the (1) type of command (write, read or erase) and (2) address of a logical block in the memory where the command is to be executed. Each logic block is associated with a physical block of memory 22 in a one to one correspondence in a logic block address/physical block address conversion table (not shown) in memory device 2. The logic block address/physical block address conversion table converts the logic block address issued by host 1 into a physical block address that is processed in device 2. A random access memory (RAM) 23 included in flash memory device 2 is coupled to the controller 21. If necessary or desirable, the RAM 23 can be included in the controller 21. Flash memory 22 also includes a buffer 221 and a refresh management table 222.

The flash memory device 2 and host 1 can be integrated with each other in a system such as an MPEG music player via an IDE (ATA) Interface, for example. The host 1 can also be a personal computer (PC), and the flash memory device 2 can be a separate device, such as a device coupled to the PC, for example a SSD (Solid State Drive), via an interface such as an IDE or a universal serial bus (USB). The interfaces couple the command issued by the host 1 to flash memory device 2.

The flash memory 22 also includes a management area, as well as a user data area. Data in the refresh management table 222 are stored in a non volatile manner in the management area of the flash memory 22. By using the refresh management table 222, the controller 21 records the number of times data have been read and erased from each physical block of memory 22.

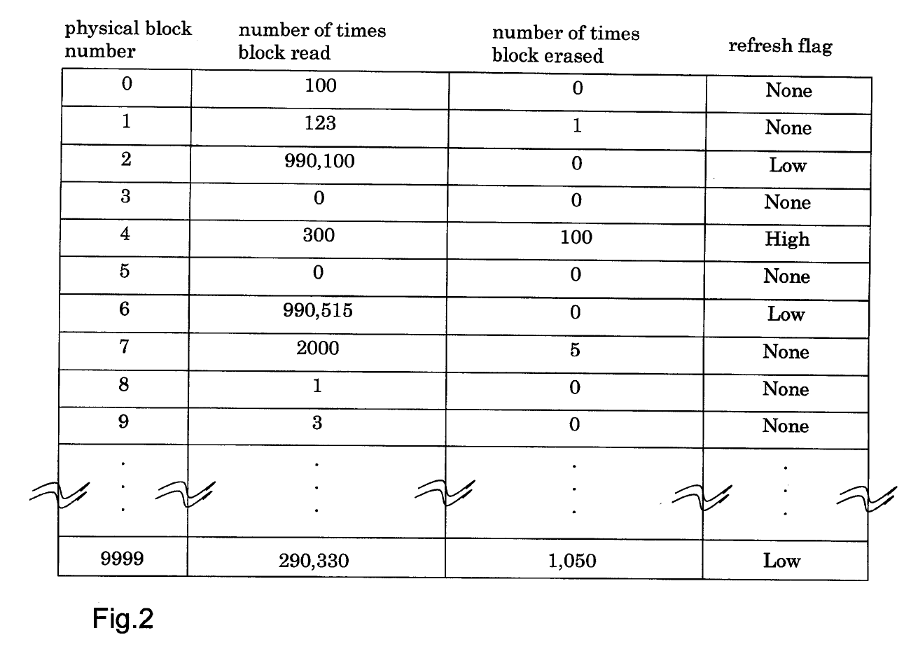

When the system of FIG. 1 is powered on, the refresh management table 222 is coupled to and spread out in the RAM 23 from the management area of the flash memory 22. The exemplary table 222 of FIG. 2 is based on flash memory 22 having 10,000 physical blocks. When the controller 21 reads data from a particular physical block of memory 22, the controller 21 records/updates an indication in the refresh management table 222 of the number of times data have been read from the particular block (the indication is in the “number of times data are read” column of FIG. 2). When the controller 21 erases data from a particular physical block of memory 22, the controller 21 records/updates an indication in the refresh management table 222 of the number of times data have been erased from the particular block (the indication is in the column “number of times data erased” column of FIG. 2). (Erase, by definition, includes erasing and rewriting data of the block).

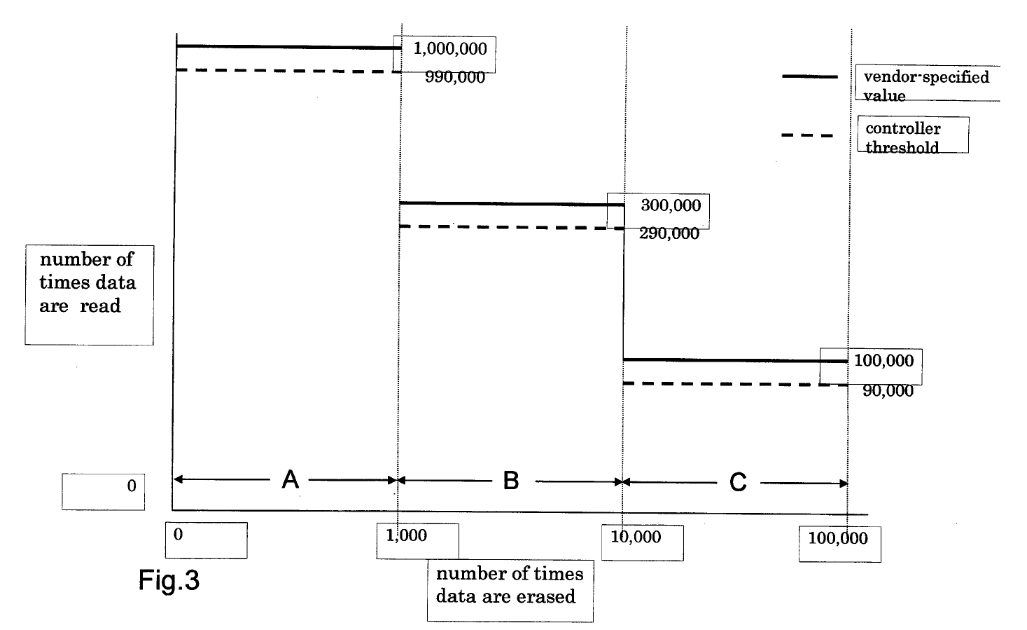

The limit on the number of data read operations for a particular physical block depends on the number of data erasures that have been executed on the particular physical block in the past. In general, the limit tends to decrease as the number of data erasures that have been executed in the past on the particular data block increases (see FIG. 3). As shown in FIG. 3, if the number of data erasures (total of data erasures) of a particular physical block is in the range of 0to 999 times, the limit on the number of read cycles for the particular block (vendor-specified value in FIG. 3) is 1,000,000 times (range A in FIG. 3). If the total number of data erasures for a particular block is in the range of 1,000 to 9,999, the vendor-specified value on the number of data read cycles for the particular block is 300,000 (range B in FIG. 3). If the number of data erasures is in the range of 10,000 to 99,999 times, the vendor-specified value is 100,000 times (range C in FIG. 3). In the embodiment of FIG. 3, each of the controller thresholds established for ranges A, B, and C of FIG. 3 is set to a smaller value than the vendor-specified value. If the number of times data have been read from a physical block has reached the controller threshold, controller 21 sets, in the refresh management table 222, a Low refresh flag for the physical block indicated by “Low” in the “refresh flag” column of FIG. 2.

In the prior art refresh method, when the controller 21 receives a data read command from the host 1 and the number of times data have been read from a particular physical block is found to have reached its vendor-specified limit, the data read operation by a CPU (not shown) within controller 21 is interrupted to refresh the physical block. In the embodiment of FIG. 1, refresh operations by the CPU in controller 21 are collectively executed after the refresh management table 222 has performed the method discussed hereinafter.

In this case, if the controller threshold that is a criterion for executing a refresh operation is set to the same value as the vendor-specified value, the number of read data cycles is likely to exceed the above-described limit in the time interval between host 1 issuing the data read command and the start of a refresh operation. It is annoying for a user of a system including device 2 for such a limit to be exceeded because it causes an interruption in the operation of host 1. For this reason, the controller threshold is set to a value lower than the vendor-specified value so that a refresh is effectively executed before the number of times data read from a particular physical block reaches its vendor-specified limit.

If the power supply of the device 2 is shut off or disconnected from the device 2, the data of the refresh management table 222 are recorded in a non-volatile manner in the management area of flash memory 22, and the table 222 is coupled to and spread out in the RAM 23 the next time power is supplied to the system. Also, because the power supply might be shut off or disconnected from device 2 for some reason, it is preferable for the data of the refresh management table 222 in the RAM 23 to be periodically (e.g. every 10 minutes) recorded or updated in a management area of the flash memory 22.

Auto-Refresh

Controller 21 automatically executes a refresh by using an internal timer and a firmware program previously installed in the controller 21. The firmware program is executed on the basis of a timed event, e.g. a particular time associated with the start of a workday.

Controller 21 can execute an auto-refresh operation on the firmware program at predetermined periodic time intervals, e.g. once every several seconds or once every several minutes, while the device 2 is powered on. Because the power of device 2 is on at all times in many systems, the program can cause the auto-refresh operation to be executed at a predetermined time, e.g. 9:00 am, in the morning.

If the timed event occurs and host 1 has not supplied a write or read command to the controller 21 and a (Low) flag is set for one or more physical blocks when the timed event occurs, the controller 21 executes a refresh of the physical blocks having the set Low flag.

To this end, controller 21 searches for physical blocks having a set Low refresh flag in the refresh flag column of the refresh management table 222 indicated in FIG. 2. For each such physical block, the CPU of the controller 21 reads the “number of times” data in the second and third columns (FIG. 2) of table 222. If the search indicates there are plural physical blocks having a set Low refresh flag, the CPU of controller 21 determines, from the number of times data have been erased in the third column of FIG. 2 for each of the blocks having the Low refresh flag, to which of the three ranges (A, B or C, FIG. 3) each physical block having a Low refresh flag belongs. For example, block 9999 belongs to range B because it has been erased 1,050 times while blocks 2 and 6 belong to range A because they have been erased zero times, but have been read 990,200 and 990,515 times, respectively. Then, the physical blocks are sequentially refreshed in descending order based on the number of times data exceeding the controller threshold have been read from the physical blocks. Hence, in the example of FIGS. 2 and 3, blocks 6, 2 and 9999 are refreshed in sequence because they have been respectively read 990,515, 990,100 and 290,330 times. A refresh is sequentially executed on a block by block basis. Alternatively, controller 21 refreshes the physical blocks in descending order based on the difference between the controller threshold or the vendor-specified value and the number of times data have been read. In the example of FIGS. 2 and 3, block number 6 is refreshed before block 9999, which is refreshed before block 2 because blocks 6, 9999 and 2 respectively exceed their controller thresholds by 515, 330 and 100 times.

In FIG. 3, the differences between the vendor-specified values of the number of data read operations (i.e. cycles) and controller threshold values for the number of data read operations in each range (A, B and C) are identical to one another, i.e. 10,000. Therefore, the prior art refresh order is somewhat similar to the refresh order determined by controller 21.

However, because the controller thresholds are set to differ in each of ranges (A, B and C), the prior art refresh order differs from the refresh order of memory device 2. By using the above-mentioned two methods, the physical blocks are refreshed in descending order of the likelihood of causing a read disturb error. Thus, a read disturb error is more reliably prevented.

If the timed event occurs when the controller 21 is executing a media access (data read) in response to a command from the host 1 and if multiple physical blocks are required to be refreshed, a refresh is executed at given or predetermined periodic time intervals, from the start of refresh of one physical block to the start of a refresh of the next physical block, for each physical block.

It takes 100 ms (milliseconds), at the most, from the start of a refresh of one particular physical block to the completion of the refresh operation for that particular block. For this reason, the refresh interval can be set to, e.g., 1 second. That is, a refresh operation is executed in a time-sharing manner i.e. by interrupting the continuous media access.

Thus, even if there are plural blocks required to be refreshed in the ongoing process, the transfer of data read from flash memory 22 to host 1 is not interrupted for a long time interval. In particular, even if music, moving images or the like are stored in the flash memory 22 and plural physical blocks reach a status requiring simultaneous refreshing, a high data transfer rate from memory 22 to host 1 is maintained by refreshing such plural physical blocks in a time-sharing manner. Thus, the user does not realize refreshing is occurring and is not annoyed by the refreshing action.

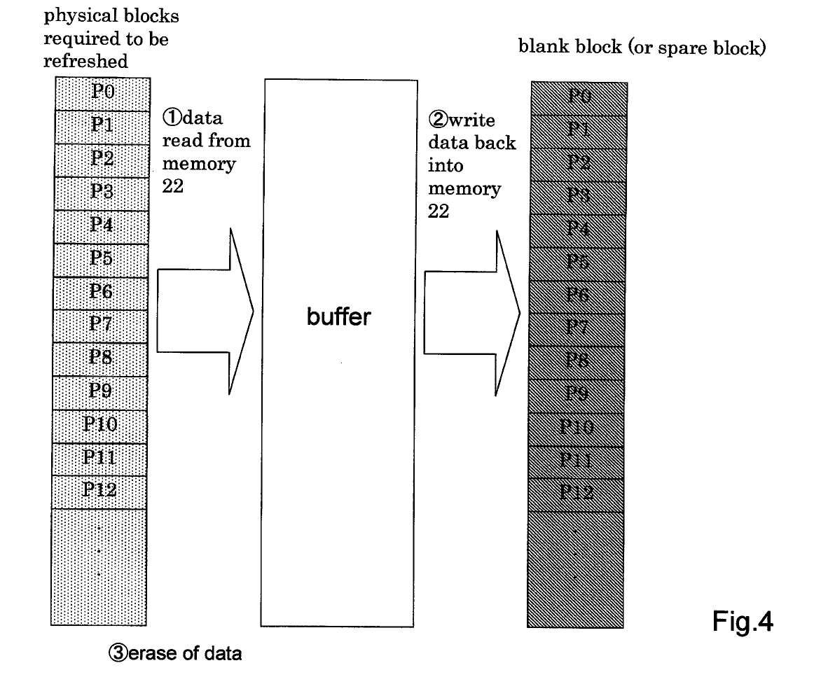

The refresh method will now be specifically described with reference to FIG. 4. First, the CPU of controller 21 scans memory 22 to find, select and allocate, for the refresh operation, one of the blank blocks (not shown) of memory 22. Next, the CPU of controller 21 reads out all the data of the physical block needing refreshing to buffer 221 in flash memory 22; the read out is in sequential page units of the block needing refreshing. Then the CPU writes all the data in buffer 221 to the blank block in memory 22. All the data in the original block are erased, followed by updating of (1) the logic block address/physical block address conversion table and (2) the blank block in the blank block table (not shown) within the management area of the flash memory 22. Also, the indication in the second column of table 222 of the number of times data have been read from the original block is reset to “0” and the indication in the third column of table 222 for the number of times the physical block has been erased is incremented by 1 (one). In addition, the “Low” refresh flag for the block which has been refreshed is canceled, and the refresh flag for the refreshed block is set to “None.” In this embodiment, the refresh operation also can be executed using both a spare block and a spare block table within the management area of the flash memory 22.

In the prior art, first, 1) data of a physical block are temporarily stored in a buffer, next, 2) the data of the physical block are erased, and then 3) the buffer-stored data are rewritten to the original block. In the prior art, if the power supply is shut off or disconnected from device 2 for some reason after execution of eraser step 2) and before execution of rewriting step 3), the original data are completely erased, i.e., lost. By using a controller and method as described above, if there is a power supply failure or other interruption, the original data are not lost.

Refresh operation in response to a COMMAND from host 1

Besides the auto-refresh mentioned above, the refresh can also be executed in response to host 1 issuing a predetermined command to controller 21, as can occur when the host 1 is not performing a media access. To this end, the following commands are programmed in driver software of the host 1.

1. Get Refresh Pending Status Command

This is command from host 1 causes controller 21 to notify the host 1 of the number of physical blocks having a set “Low” or “High” refresh flag (discussed later) in the refresh management table 222 of flash memory 22, or as spread out in RAM 23.

2. Execute Refresh Command

This command from host 1 causes controller 21 to perform a refresh operation on one or more physical blocks of memory 22. The number of the physical blocks to be refreshed is specified by this command. This command also includes the logic block address(es) of the block(s) to be refreshed; the address converter in controller 21 converts the logic block address(es) to the appropriate physical block address(es).

3. Save Refresh Table Command

This command from host 1 causes the controller 21 to transfer data stored in refresh management table 222 into the management area of flash memory 22. Upon completing such storing, this command is completed.

The following command-issue order of host 1 is preferable.

a) Host 1 initially supplies to controller 21 the GET REFRESH PENDING STATUS COMMAND so the controller is supplied with an indication of the number of physical blocks required to be refreshed.

b) Host 1, responds to a signal that controller 21 derives (the controller 21 derives indicates the controller 21 has found the blocks required to be refreshed) by supplying the EXECUTE REFRESH COMMAND to controller 21 at a time while the controller 21 is not performing a media access. Controller 21 responds to the EXECUTE REFRESH COMMAND by executing a refresh according to the program stored in the controller 21. The EXECUTE REFRESH COMMAND enables the refresh to be executed only when it should be done, to improve system performance.

c) Host 1 then supplies to controller 21 the SAVE REFRESH TABLE COMMAND to cause the controller 21 to transfer, in a non-volatile manner, the data of refresh management table 222, into the management area of the flash memory 22; controller 21 performs the transfer at a predetermined time interval. As a result of this command, data of refresh management table 222 are efficiently protected, (i.e., cannot be lost) even though the power supply might, for some reason, shut down or be disconnected from system (host 1 and device 2) during the transfer.

According to the above embodiment, the refresh operation essentially does not interrupt the transfer of digital data, such as music or moving images, to the host 1 from flash memory 22 interrupted so the user is not annoyed by the refresh operation.

Coping with Bit Errors

When user data are written to a flash memory, an error check code created during the data write operation is added to the user data. When the data are read from the flash memory, they are checked according to the error check code by an error correcting circuit (not shown) within the controller 21 to determine whether or not there is an error in the written data. If the number of bit errors is within the ability of the controller to correct the errors (e.g. 8 bits or less), the bit errors can be corrected. If the number of bit errors is more than the ability of controller 21 to correct the errors, the bit errors can not be corrected. This means that the block has become a bad (i.e. defective) block due to numerous data write or erase cycles being executed in the block.

Accordingly, to assure safety in the refresh method discussed above when the number of bit errors in a particular physical block reaches a predetermined number (referred to as “bit error threshold”, e.g. 7 bits) greater than the ability of the controller to correct the errors (referred to as “controller ability value”, e.g. 8 bits), the data of such a physical block are rewritten to a spare block and the original physical block that had been used until that time is regarded as a bad block.

In that case, the CPU of controller 21 sets a “High” refresh flag for such a physical block in refresh management table 222 (see the “refresh flag” column in FIG. 2).

In FIG. 2, the “High” refresh flag is set for the physical block number “4”. Because the “High” flag is set, physical block “4” is regarded as a bad block. Controller 21 responds to the High flag associated with block 4 by writing the data of bad block 4 to a spare block of memory 22 prior to the controller refreshing any physical block having a Low flag due to the number of data read cycles having reached its controller threshold. This action by controller 21 is considered an emergency.

Coping with such an emergency is also performed by controller 21 (1) temporarily storing in buffer 221 the corrected data of a block detected as having an error, (e.g. block 4) (2) then rewriting the stored data in buffer 221 to the spare block (not shown) in memory 22, then updating, in the logic block/address block conversion table, the logic block address associated with the physical block address where the data formerly stored in the bad block are now stored , and (3) then updating the contents of the spare block table. The bad blocks are kept in mothballs. Even though these actions of rewriting the data of the bad block to the spare block, to cope with bit errors, are not exactly a refresh, such rewriting is treated as a “refresh” by memory device 2 of FIG. 1. This is because such a bad block is also managed in refresh management table 222 and the data of the original block are rewritten to the spare block in almost the same way as a refresh. Thus, a refresh and coping with a bad block are efficiently executed in a collective manner. As a result, system performance is improved.

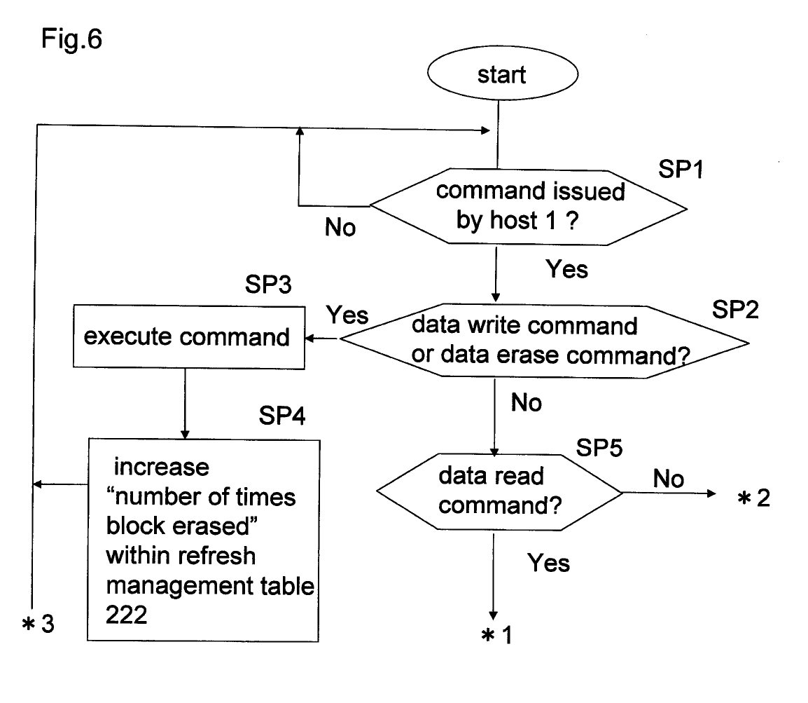

Next, an exemplary management operation performed by controller 21 in response to a command issued by host 1 is described by referring to FIGS. 6-8. As indicated by step SP1 (FIG. 6), controller 21 is always monitoring the output of host 1 to determine whether host 1 is issuing a command for a logical block address in memory 22. If controller 21 recognizes that host 1 issued a command, (1) the logical address/physical address conversion table of memory 2 responds to the logic address and converts it into a physical table address, and (2) controller 21 determines whether the command is a data write command or a data erase command (step SP2). If the determination by step SP2 is “yes”, controller 21 executes step SP3, a command causing controller 21 to increase the indication, in refresh management table 222, of the “number of times data are erased” from the physical table address by 1 (one); such incrementing of the indication in table 222 is performed in step (SP4). The initial value of the “number of times data are erased” is “0.” After step SP4 has been completed, the program returns to step SP1 and controller 21 waits for a new command from host 1.

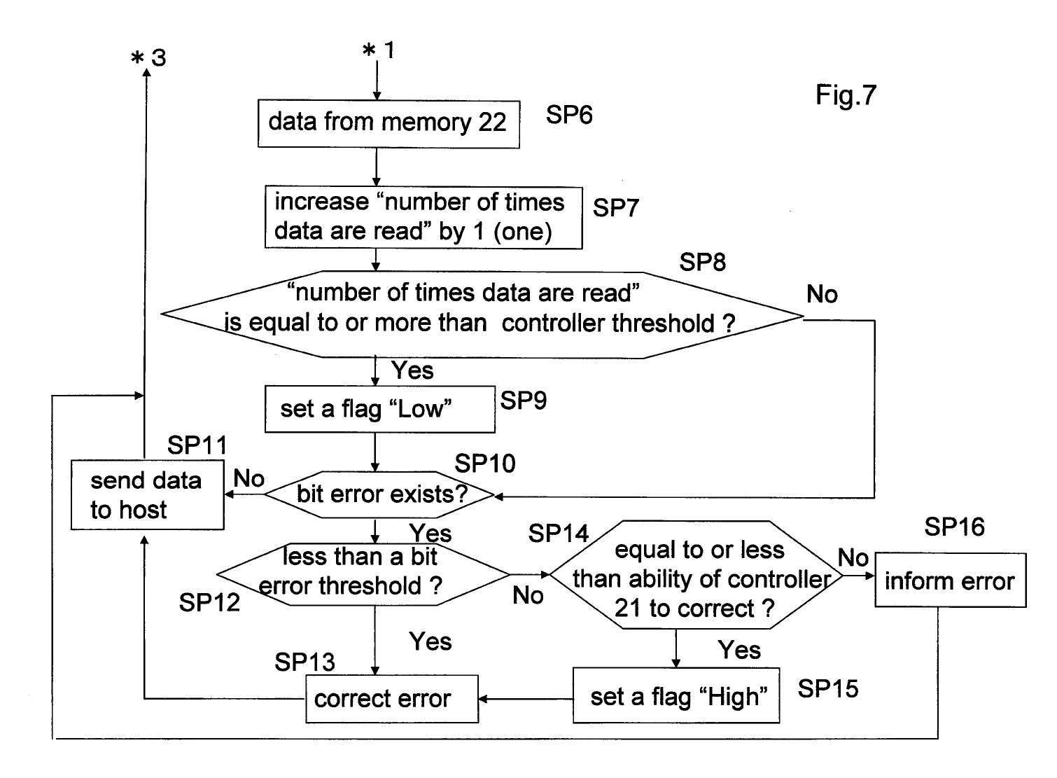

If the result of step SP2 is “No,” controller 21 determines whether the command issued by host 1 for the particular physical data block is a data read command (SP5). If the determination by step SP5 is “yes”, operation proceeds to step SP6 (FIG. 7), during which controller 21 commands readout of data from the particular physical data block of memory 22.

Then the program of controller 21 advances to step SP7, during which controller 21 increases by 1 (one) the indication in table 222 for the “number of times data are read,” for the physical block of memory 22 corresponding to the logic block address issued by host 1. Next, controller 21 determines, during step SP8, for the physical block corresponding to the logic block address issued by host 1, whether the “number of times data are read” is equal to or more than the appropriate controller threshold indicated by one of the dotted lines of FIG. 3. As discussed previously, the thresholds set into controller 21 (controller thresholds) are slightly less than the vendor thresholds (vendor specified value) based on the number of times data are read, as a function of the number of times data are erased. If the result of step SP8 is “yes”, the controller 21, during step SP9, sets a Low flag in the refresh management table 222, for the command-executed physical block number. Then operation proceeds to step SP10, during which controller 21 determines whether a bit error exists in the data read from memory 22 in response to the command issued by host 1. If the result of step SP10 is “No”, controller 21, during step SP11, sends the data read from memory 22, as is, to the host 1. If the result of step SP10 is “yes,” controller 21 determines, during step SP12, whether the number of bit errors is less than the bit error threshold. If the result of step SP12 is “yes”, controller 21 corrects such a bit error during step SP13. Then controller 21 sends the data read from the executed physical block of memory 22 with the corrected data to the host 1, as indicated by step SP11. If the number of bit errors is equal to or more than the bit error threshold (“No” in step SP12), controller 21 determines, during step SP14, whether the number of bit errors is equal to or less than the ability of controller 21 to correct the error. If the result of step SP14 is “yes”, the controller 21, during step SP15, sets a “High” refresh flag in the refresh management table 222 for the command-executed physical block number. In addition, controller 21 corrects such a bit error, as indicated by step SP13, and then sends the corrected data to host 1, as indicated by strep SP11. If the number of bit errors exceeds the ability of controller 21 to correct the bit errors, controller 21 sends a “system error” signal to host 1 (SP16).

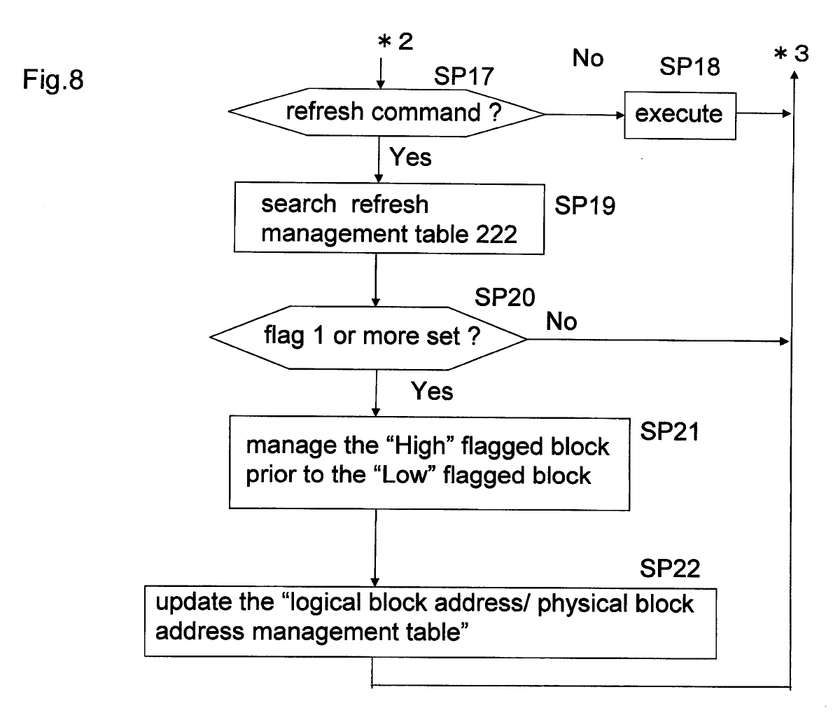

If the result of step SP5 is “No” (i.e., the command issued by host 1 to memory device 2 is not a data write command, a data erase command, or a data read command), the program of controller 21 proceeds to step SP17, during which controller 21 determines whether the issued command is a refresh command (see FIG. 8). If the result of step SP17 is “No,” controller 21 executes the issued command during step SP18. If the result of step SP17 is “yes”, controller 21, during step SP19, searches, during step SP20, the refresh flag entries of refresh management table 222 to determine whether a “High” and/or “Low” flag is set. If the result of step SP20 “yes” and both the “High” and “Low” flags are present, the controller 21 initially performs the previously described “High” flag, and then performs one or more the previously described “Low” flags (SP21). Then, during step SP22, controller 21 updates the “logical block address/physical block address management table”. After step SP22 has been completed, the program returns to step SP1

If the RAM 23 is externally connected to the controller 21, the RAM may be a conventional random access memory, or a dynamic random access memory (DRAM) or a SDRAM (synchronous DRAM).

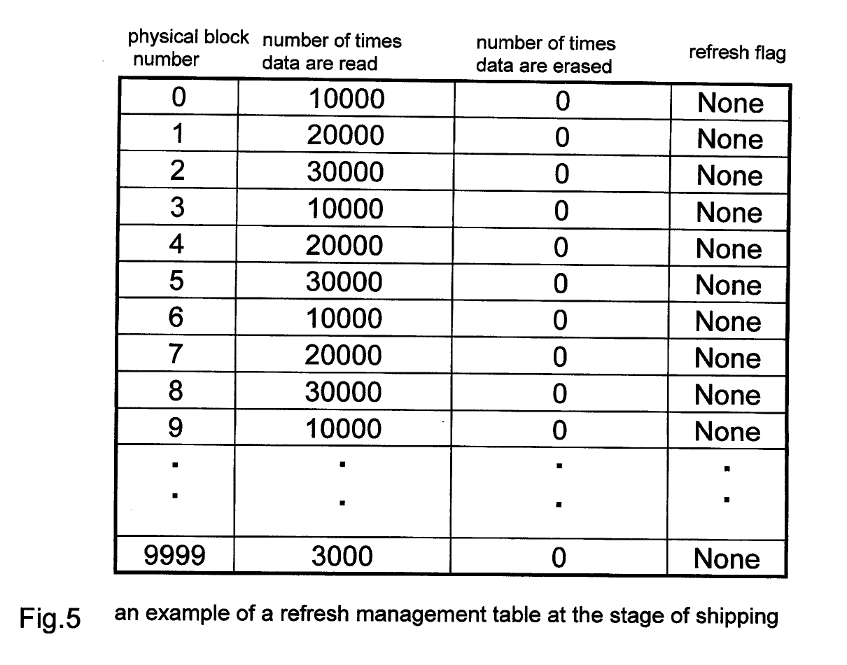

In addition, as shown in FIG. 5, different values for the number of times data are read (as dummy data) are set for each physical block of memory 22 in the refresh management table 222. The different values of FIG. 5 are set by the vendor of device 2 before shipping of the memory system. Setting these different values in table 222 enables the refresh to be performed in a further divided manner and suitable to such a system that constantly performs a sequential data read.

In a game machine or the like, the data stored in memory 22 are read many times during a day. Generally, the audio and video data stored in memory 22 are managed in a file having data composed of multiple physical blocks.

In such a case, it is preferable for device 2 to record in refresh management table 222 the number of times every file which accommodates audio and video data representing the contents of such a game are read. Controller 21 commands table 222 to increase the number of times the file of such a game is read when device 2 is turned on every morning. In response to turn on of device 2, controller 21 also (1) retrieves from table 222 the daily maximum number of times such files can be read without exceeding the limit on the number of times such files can be read or (2) calculates a daily average of the number of times each such file has been read up to the previous day. These actions enable controller 21 to anticipate whether a refresh flag for a particular physical block is likely to be set during the day. In response to the anticipated result being “yes,” controller 21 refreshes the physical block(s) before device 2 is activated to a state that enables players to use the system that day. This is a feed-forward control.

While there have been described plural embodiments of the invention, it will be clear that variations in the details of the embodiments specifically illustrated and described can be made without departing from the true spirit and scope of the invention, as defined in the appended claims.

1. A method of refreshing a flash memory storing many physical data blocks, the flash memory being in a flash memory device including a refresh management table storing indications of the number of times individual physical data blocks of the flash memory have been read and erased, comprising:
using the refresh management table to assist in storing, updating and managing the individual physical data blocks so that an individual physical data block is individually refreshed in response to the individual physical data block reaching or exceeding a controlled limiting threshold value for the number of times the individual physical data block can be read without being refreshed.

2. The method according to claim 1 wherein the controlled limiting threshold value is less than a vendor-specified value for the number of times the individual physical data block can be read without being refreshed.

3. The method according to claim 1, wherein the refresh is executed as a timed event even during media access of the flash memory device.

4. The method according to claim 1, wherein in response to the refresh management table indicating plural physical data blocks simultaneously require refreshing, sequentially individually performing the refreshes of such plural physical data blocks.

5. The method according to claim 4, wherein the controlled limiting threshold value is less than a vendor-specified value for the number of times each individual physical data block can be read without being refreshed and the plural physical data blocks simultaneously requiring refreshing are refreshed in descending order based on the proximity of the number of times that a particular data block has been read relative to the vendor-specified limiting threshold value for each particular data block, so that the physical data block that has been read the number of times closest to the vendor-specified value without being refreshed is refreshed prior to the remaining physical data blocks requiring refreshing, and the physical data block that has been read the number of times second closest to the vendor-specified value without being refreshed is refreshed prior to the remaining physical data blocks requiring refreshing.

6. The method according to claim 1 wherein a host issues a refresh command to a controller for the flash memory of the flash memory device while the controller is not to media stored in the flash memory device.

7. The method according to claim 1, wherein a system including the memory device includes a table indicating a relationship between addresses of the physical data blocks and addresses of logic data blocks corresponding with the physical data blocks, and the refresh of each individual physical data block is executed by:
(a) temporarily storing the data of the individual physical data block in a buffer of the flash memory device,
(b) then writing the data of the individual physical data block temporally stored in the buffer to a spare blank block of the flash memory device,
(c) then erasing the data from the physical block of the flash memory device where the original data that were temporarily stored in the buffer memory were stored, and
(d) then updating the table indicating the relationship between the addresses of the physical data blocks and the addresses of logic data blocks so that the table indicates the physical data block is stored at the address of the spare block into which the data of the individual physical data block were written.

8. The method of claim 1 wherein one or more condition(s) of the data in an individual physical data block stored in the flash memory is considered as an emergency condition, and the method further comprises responding to an indication of an emergency condition in an individual physical data block by refreshing the individual physical data block indicated to have an emergency condition prior to refreshing other physical data blocks that require refreshing on a non-emergency basis.

9. The method of claim 8 wherein one of the emergency conditions is indicated by the number of bit errors of data stored in an individual block exceeding a limit value indicating data are incorrectly stored in the individual block.

10. The method according to claim 1, wherein the flash memory includes a management area having an area for storing the data of the refresh management table in a non-volatile manner, the method further comprising responding to power being applied to a system including the memory device by: (a) spreading out the contents of the refresh management table to a controller of the flash memory or to a random access memory externally connected to the controller, (b) then storing and updating indications in the spread out refresh management table of the number of times data have been read and erased for each physical data block, and (c) then performing a refresh for each physical data block in the spread out refresh management table; and responding to the removal of power to the system including the memory device by storing, in a non-volatile manner in the flash memory, the stored data of the refresh management table.

11. The method according to claim 1 further including setting the controlled limiting threshold value for the number of times the individual physical data block can be read without being refreshed as a function of the number of times the individual physical data block has been erased so that the controlled limiting threshold value decreases as the number of times individual physical data block has been erased increases.

12. The method according to claim 1, further including setting, in the refresh management table before shipping by a vendor of the memory device, different dummy data indicating the number of times data have been read from each physical block.

13. The method according to claim 1, wherein the refresh is executed on a game machine as a timed event even during media access of the flash memory device, the game machine being of a type that is expected to stay in a powered on state for a predetermined duration each time the game machine is powered on, the method further comprising: recording, during each power on period, the number of times every file which accommodates the contents of the game machine has been read from the flash memory, responding to the current turn on of the game machine by (a) retrieving an indication of the maximum number of times the file has been read prior to the current game machine turn on, or (b) calculating an average of the number of times each file has been read each time the machine has been powered on; determining whether an individual physical data block stored in the flash memory is anticipated to require refreshing during the current turn on time of the game machine, the determined anticipated result being based on (a) or (b), and responding to the determined anticipated result being “yes,” by refreshing the individual physical data block anticipated to require refreshing before the game machine is activated for use by player(s) of the game machine.

14. A flash memory device comprising a flash memory for storing many physical data blocks, a refresh management table for storing indications of the number of times each individual physical data block has been read, a controller adapted to be responsive to read and erase control signals from a source external to the flash memory device and to the stored indications of the refresh management table for controlling reading, erasing and refreshing of the individual physical data blocks of the flash memory so that in response to the number of times each individual physical data block has been read being equal to or exceeding a limit value, the individual physical data block associated with the indication equaling or exceeding the limit value is caused to be refreshed.

15. The flash memory device of claim 14 wherein the table is arranged for storing indications of the number of times the individual physical data blocks have been erased, and the controller is arranged so the limit value depends on the number of times the individual physical data blocks have been erased.

16. The flash memory device of claim 14 wherein the controller is arranged to respond to (a) conditions of the data blocks read from the flash memory for determining that an emergency refresh of a particular data block os requried, and (b) the determination of the emergency refresh by refreshing the particular data block determined to require the emergency refresh prior to the data block(s) that is refreshed based on the number of times the data block has been refreshed.

17. The flash memory of claim 16 wherein the emergency refresh depends on the number of bit erros in a data block.

18. The flash memory device of claim 14 wherein the limiting value for each physical data block is less than a vendor-specified value for the number of times each individual physical data block can be read without being refreshed, the controller being arranged so that in response to plural physical data blocks simultaneously requiring refreshing such plural physical data blocks are refreshed sequentially in descending order based on the proximity of the number of times that a particular data block has been read relative to the vendor-specified limiting threshold value for each particular data block, so that the physical data block that has been read the number of times closest to the vendor-specified value without being refreshed is refreshed prior to the remaining physical data blocks requiring refreshing, and the physical data block that has been read the number of times second closest to the vendor-specified value without being refreshed is refreshed prior to the remaining physical data blocks requiring refreshing.
